(19) United States
(12) Patent Application Publication
(10) Pub. No.: US 2014/0027263 A1
(43) Pub. Date: Jan. 30, 2014

(54) TOUCH PANEL AND METHOD FOR MANUFACTURING SAME

(71) Applicant: PANASONIC CORPORATION, Osaka (JP)

(72) Inventors: Koji TANABE, Osaka (JP); Keishiro MURATA, Kyoto (JP)

(21) Appl. No.: 13/933,941

(22) Filed: Jul. 2, 2013

(30) Foreign Application Priority Data
Jul. 27, 2012 (JP) 2012-166771

(51) Int. Cl. H03K 17/96; H05K 3/10

(52) U.S. Cl. CPC H03K 17/962; H05K 3/10
USPC 200/600; 29/622

(57) ABSTRACT

A touch panel includes a translucent substrate; a plurality of translucent lower conductive layers formed along a first direction of an upper surface of the substrate; a translucent curable insulating layer covering entire surfaces of the lower conductive layers; and a plurality of translucent upper conductive layers formed in a second direction perpendicular to the lower conductive layers on an upper surface of the curable insulating layer.

### TECHNICAL FIELD

The present technical field relates to a touch panel mainly used in operations of various electronic apparatuses and a method for manufacturing the touch panel.

### BACKGROUND ART

Recently, various electronic apparatuses such as portable telephones and electronic cameras have had more advanced functions and become diversified. Electronic apparatuses including a translucent touch panel mounted to a front surface of a display device such as a liquid crystal display device have been developed. When a user operates a touch panel with a finger or the like while the user views display on a display device through the touch panel, various functions of an electronic apparatus are switched. Electronic apparatuses, which are capable of being reliably operated by a user and less expensive, have been demanded.

FIG. 5 is a sectional view of conventional touch panel 10. FIG. 6 is an exploded perspective view of conventional touch panel 10. For easy understanding of a configuration, dimensions are partially enlarged. Touch panel 10 includes upper substrate 1, lower substrate 4, and cover substrate 7. A plurality of belt-shaped translucent upper conductive layers 2 is formed in a predetermined direction on an upper surface of film-shaped translucent upper substrate 1. Upper conductive layer 2 is made of, for example, indium tin oxide. Each of upper electrodes 3 has one end connected to an end portion of each of upper conductive layers 2 and another end extending to the right end of the outer periphery of upper substrate 1. Upper electrode 3 is made of, for example, silver and carbon.

A plurality of belt-shaped translucent lower conductive layers 5 is formed in a direction perpendicular to upper conductive layers 2 on an upper surface of film-shaped translucent lower substrate 4. Lower conductive layer 5 is made of, for example, indium tin oxide. Each of lower electrodes 6 has one end connected to an end portion of each of lower conductive layers 5 and another end extending to the right end of the outer periphery of lower substrate 4. Lower electrode 6 is made of, for example, silver and carbon.

Upper substrate 1 is overlaid on the upper surface of lower substrate 4, and plate-shaped or film-shaped translucent cover substrate 7 is overlaid on the upper surface of upper substrate 1. They are respectively attached to each other with adhesive layers 8 and 9 including an adhesive agent as material. Thus, touch panel 10 is configured.

Touch panel 10 is disposed on a front surface of a display device such as a liquid crystal display device (not shown) and mounted to an electronic apparatus (not shown). Upper electrodes 3 extending to the right end of upper substrate 1 and lower electrodes 6 extending to the right end of lower substrate 4 are electrically coupled to an electronic circuit (not shown) of the electronic apparatus via a flexible wiring board, a connector (not shown), or the like.

In a state in which a voltage is applied between upper electrodes 3 and lower electrodes 6 from the electronic circuit, an operator carries out operations by touching an upper surface of cover substrate 7 with a finger or the like, according to display on a display device on a rear surface of touch panel 10. Then, a capacitance between upper conductive layer 2 and lower conductive layer 5 in an operated place is changed. As a result, the operated position is detected by the electronic circuit, so that various functions of the electronic apparatus are switched.

For example, when an operator touches the upper surface of cover substrate 7 over a desired menu in a state in which a plurality of menus are displayed on the display device, a part of electric charge is conducted to a finger, and a capacitance between upper conductive layer 2 and lower conductive layer 5 in a contact place of touch panel 10 is changed. The change is detected by the electronic circuit, so that a desired menu is selected.

Note here that as prior art information related to this application, for example, Japanese Patent Application Unexamined Publication No. 2011-146023 is known.

### SUMMARY

A touch panel includes a translucent substrate, a plurality of translucent lower conductive layers formed along a first direction of an upper surface of the substrate, a translucent curable insulating layer covering entire surfaces of the lower conductive layers, and a plurality of translucent upper conductive layers formed in a second direction perpendicular to the lower conductive layers and on an upper surface of the curable insulating layer.

### BRIEF DESCRIPTION OF THE DRAWINGS

FIG. 1 is a sectional view of a touch panel in accordance with the present embodiment.

FIG. 2 is an exploded perspective view of the touch panel in accordance with the present embodiment.

FIG. 3A is a partial sectional view for illustrating a method for manufacturing the touch panel in accordance with the present embodiment.

FIG. 3B is a partial sectional view for illustrating the method for manufacturing the touch panel in accordance with the present embodiment.

FIG. 3C is a partial sectional view for illustrating the method for manufacturing the touch panel in accordance with the present embodiment.

FIG. 4A is a partial sectional view for illustrating the method for manufacturing the touch panel in accordance with the present embodiment.

FIG. 4B is a partial sectional view for illustrating the method for manufacturing the touch panel in accordance with the present embodiment.

FIG. 4C is a partial sectional view for illustrating the method for manufacturing the touch panel in accordance with the present embodiment.

FIG. 4D is a partial sectional view for illustrating the method for manufacturing the touch panel in accordance with the present embodiment.

FIG. 5 is a sectional view of a conventional touch panel.

FIG. 6 is an exploded perspective view of the conventional touch panel.

### DETAILED DESCRIPTION

In conventional touch panel 10, upper substrate 1 and lower substrate 4 are overlaid and attached to a lower surface of cover substrate 7. Therefore, the thickness of touch panel 10 is increased. Furthermore, a number of components of touch panel 10 is increased, thus increasing the cost.

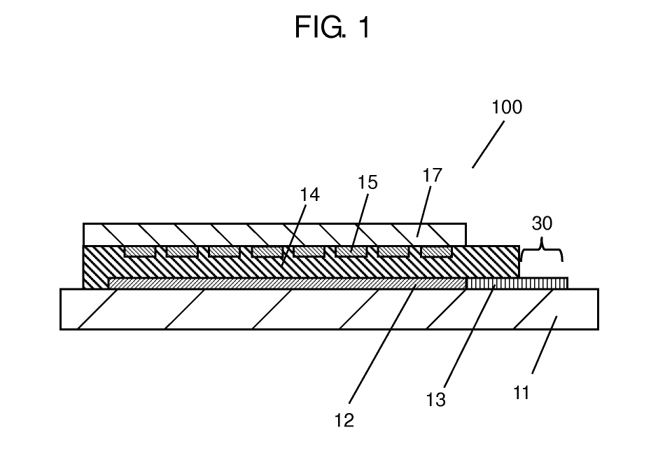

Hereinafter, the present embodiment is described with reference to FIGS. 1 to 4D. For easy understanding of a configuration, dimensions are partially enlarged.

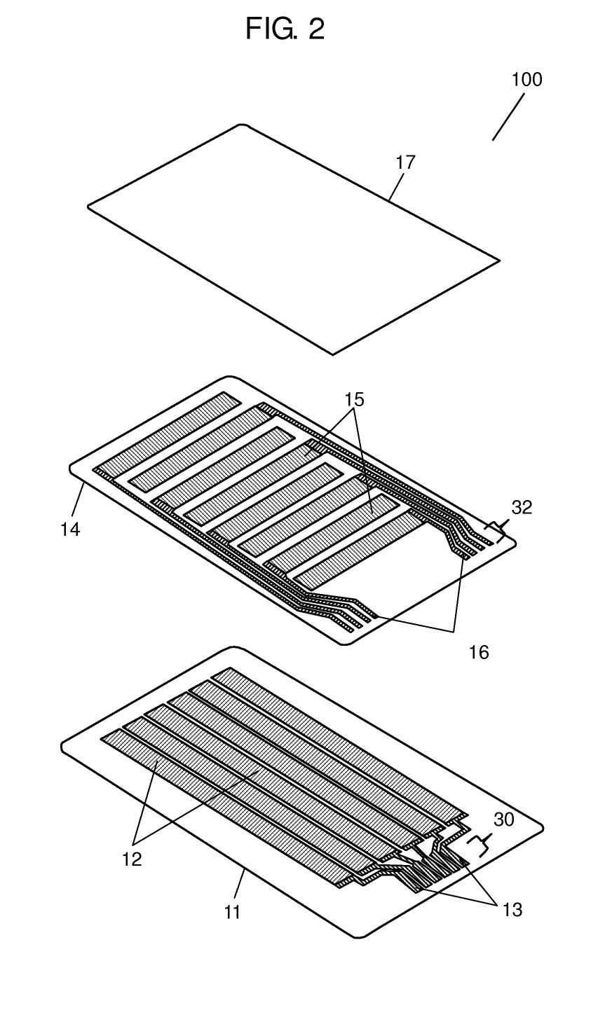

FIG. 1 is a sectional view of touch panel 100 in accordance with the present embodiment. FIG. 2 is an exploded perspective view of touch panel 100 in accordance with the present embodiment. Touch panel 100 includes translucent substrate 11, a plurality of translucent lower conductive layers 12 formed along a first direction of an upper surface of substrate 11, translucent curable insulating layer 14 covering entire surfaces of lower conductive layers 12, and a plurality of translucent upper conductive layers 15 formed in a second direction perpendicular to lower conductive layers 12 on the upper surface of curable insulating layer 14.

On the upper surface of translucent substrate 11, a plurality of belt-shaped translucent lower conductive layers 12 are arranged along a predetermined direction (first direction) by a sputtering method or the like. Substrate 11 is formed of a film of polyethylene terephthalate, polyether sulfone, polycarbonate, or the like. Lower conductive layer 12 is made of indium tin oxide, tin oxide, or the like.

Each of lower electrodes 13 has one end connected to an end portion of each of lower conductive layers 12, and another end extending to an edge portion of substrate 11 (the right end in FIG. 2). Lower electrode 13 is made of copper, nickel, silver, an alloy thereof, or the like.

Translucent curable insulating layer 14 is formed on the upper surface of substrate 11 by printing, adhesion, or the like, so as to cover lower electrodes 13 excluding extracted portion 30 at the right end. That is to say, curable insulating layer 14 covers the entire surfaces of lower conductive layers 12 and a part of lower electrodes 13. Curable insulating layer 14 is made of ultraviolet curable acrylate such as epoxy acrylate, urethane acrylate, imide acrylate, and polyester acrylate; thermosetting and translucent epoxy; or the like. A thickness of insulating layer 14 is suitably 5 μm or more, and 500 μm or less. Furthermore, for hardening, material to be hardened by using light and heat in combination may be used.

Belt-shaped translucent upper conductive layers 15 are formed along a direction (second direction) perpendicular to lower conductive layers 12 on the upper surface of curable insulating layer 14. A part of each of upper conductive layers 15 is embedded in curable insulating layer 14. In other words, the upper part of each of upper conductive layers 15 is not embedded in curable insulating layer 14 but exposed to the upper part of curable insulating layer 14. Upper conductive layer 15 is made of indium tin oxide, tin oxide, or the like.

Each of upper electrodes 16 has one end connected to an end portion of upper conductive layer 15, and another end extending to an edge portion of substrate 11 (the right end in FIG. 2). A part of each of upper electrodes 16 is embedded in curable insulating layer 14. In other words, the upper part of each of upper electrodes 16 is not embedded in curable insulating layer 14 but exposed to the upper part of curable insulating layer 14. Upper electrode 16 is made of copper, nickel, silver, an alloy thereof, or the like.

Note here that upper electrodes 16 and lower electrodes 13 are formed by pattern printing or by forming a conductive thin film by deposition or sputtering, followed by masking a predetermined pattern so as to dissolve and remove unnecessary portions.

Translucent cover layer 17 covers the upper surface of curable insulating layer 14 excluding extracted portion 32 at the right end of upper electrodes 16. That is to say, seen from the upper surface, an area of curable insulating layer 14 is larger than that of cover layer 17, and an area of substrate 11 is larger than that of curable insulating layer 14. Cover layer 17 is formed of material such as acrylate and epoxy by printing or the like. Cover layer 17 is brought into contact with the upper parts of upper conductive layers 15. As mentioned above, touch panel 100 is configured.

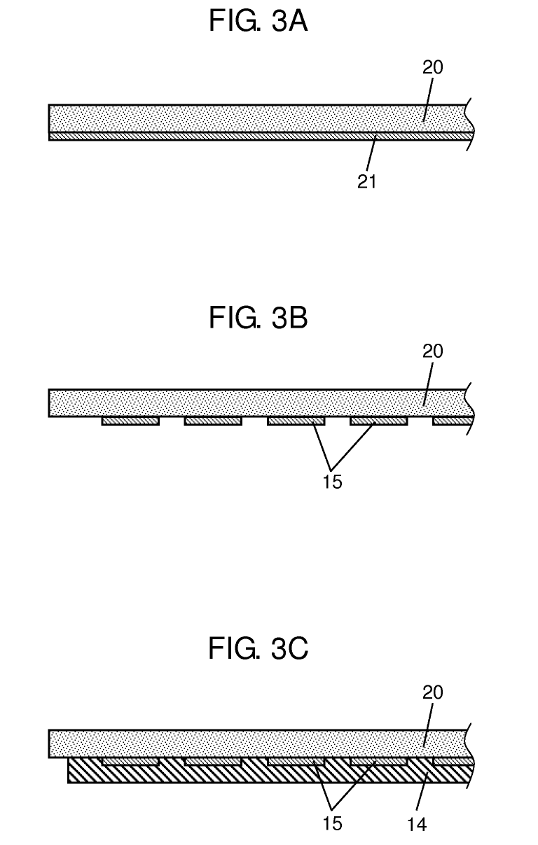

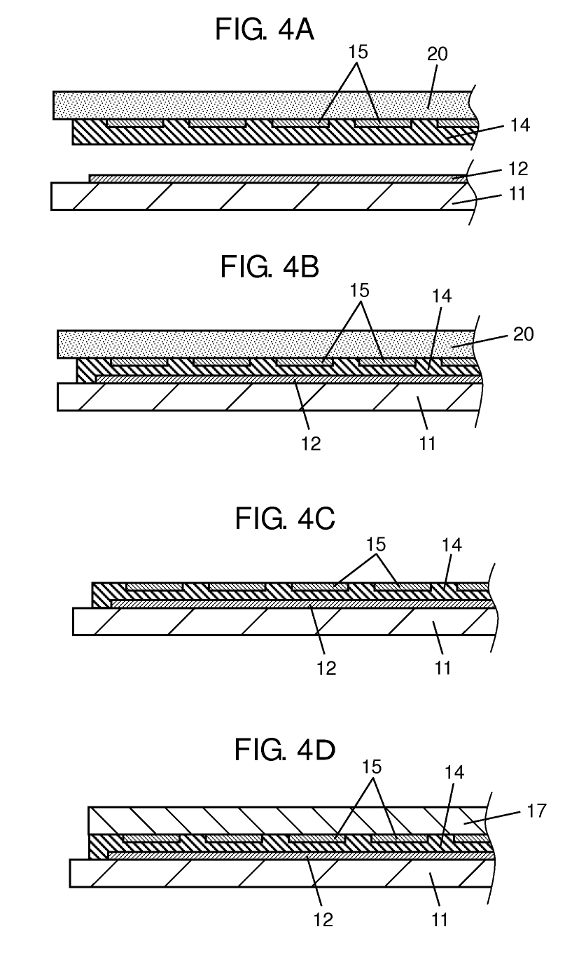

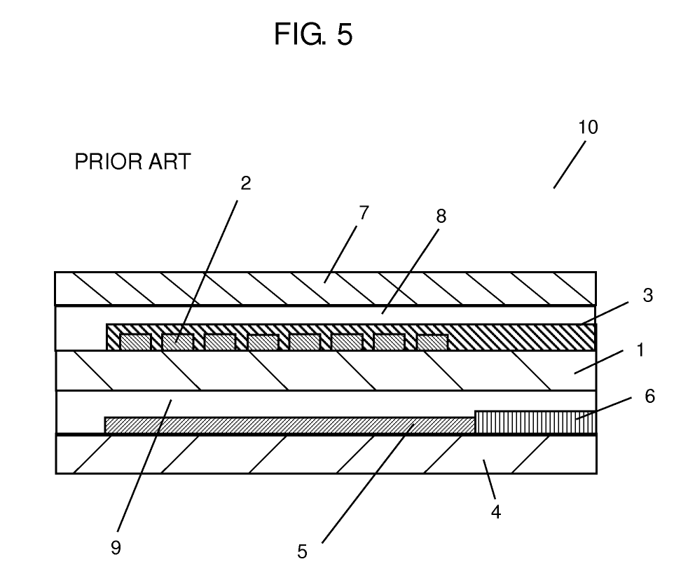

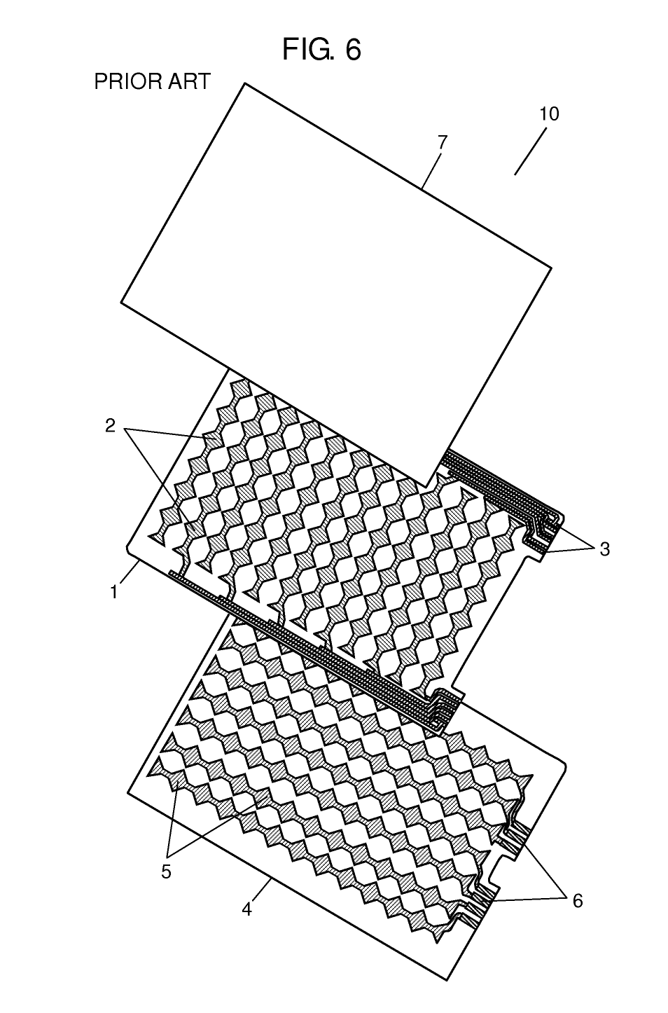

FIGS. 3A to 4D are partial sectional views for illustrating a method for manufacturing touch panel 100 in accordance with the present embodiment. Firstly, as shown in FIG. 3A, conductive thin film 21 of indium tin oxide or the like is formed on an entire surface of the lower surface of base material 20. Base material 20 is formed in, for example, a film shape, and is suitably made of material such as translucent insulating resin such as polyethylene terephthalate, polyether sulfone, and polycarbonate.

Then, patterns of upper conductive layers 15 are masked with an insulating resin film such as a dry film resist on the lower surface of conductive thin film 21, which are immersed in a predetermined etchant for dissolving and removing conductive thin film 21 in unnecessary places. As a result, as shown in FIG. 3B, a plurality of upper conductive layers 15 are formed on the lower surface of base material 20. Thereafter, as shown in FIG. 3C, curable insulating layer 14 is formed on the lower surface of base material 20 so as to cover upper conductive layers 15 by printing, adhesion, or the like.

Next, as shown in FIG. 4A, a plurality of lower conductive layers 12 is formed on the upper surface of substrate 11 by etching processing or the like. Then, base material 20 provided with upper conductive layers 15 and substrate 11 provided with lower conductive layers 12 are attached to each other with curable insulating layer 14. Thereafter, as shown in FIG. 4B, curable insulating layer 14 is hardened. When ultraviolet curable resin such as acrylate resin is used as curable insulating layer 14, curable insulating layer 14 is hardened by irradiation with ultraviolet ray. When thermosetting resin such as epoxy resin is used as curable insulating layer 14, curable insulating layer 14 is hardened by heating.

Thereafter, base material 20 is peeled off, and then upper conductive layers 15 and curable insulating layer 14 are transferred to the upper surface of lower conductive layer 12 as shown in FIG. 4C. Then, as shown in FIG. 4D, cover layer 17 is formed by printing or the like, so as to cover the upper surface of curable insulating layer 14 excluding extracted portions 32 of upper electrodes 16. In this way, touch panel 100 is configured.

Then, touch panel 100 is disposed on the front surface of a display device (not shown) such as a liquid crystal display device and mounted to an electronic apparatus (not shown). Extracted portions 30 of lower electrodes 13, which extend to the right end of substrate 11, and extracted portions 32 of upper electrodes 16, which extend to the right end of curable insulating layer 14, are electrically coupled to an electronic circuit (not shown) of the electronic apparatus via a flexible wiring board, a connector, or the like (not shown).

An operator carries out operations by touching an upper surface of cover substrate 17 with a finger or the like, according to display on a display device on a rear surface of touch panel 100 in a state in which a voltage is applied between upper electrodes 13 and lower electrodes 16 from the electronic circuit. Then, a capacitance between lower conductive layer 12 and upper conductive layer 15 in an operated place is changed. As a result, the operated place is detected by the electronic circuit, so that various functions of the electronic apparatus are switched.

For example, when an operator touches the upper surface of cover layer 17 with a finger on a desired menu in a state in which a plurality of menus are displayed on the display device, a part of electric charge is conducted to the finger, and a capacitance between upper conductive layer 12 and lower conductive layer 15 in an operated place of touch panel 100 is changed. The change is detected by the electronic circuit, so that a desired menu is selected.

In the present embodiment, lower conductive layers 12 and upper conductive layers 15 are provided with curable insulating layer 14 interposed therebetween on the upper surface of one substrate 11. Therefore, a plurality of substrates is not required to be used, and a number of components can be reduced. Furthermore, the substrates are not required to be overlaid and attached to each other. Thus, it is possible to produce touch panel 100 which can be assembled easily and which is less expensive.

Furthermore, curable insulating layer 14 is provided between upper conductive layers 15 and lower conductive layers 12, and thereby upper conductive layers 15 and lower conductive layers 12 are insulated from each other reliably. Therefore, an operation position can be reliably detected. Curable insulating layer 14 is excellent in terms of stability with respect to environmental change because it absorbs water less easily as compared with adhesive agents.

Note here that a configuration is described in which lower conductive layers 12 and upper conductive layers 15 are formed in a belt shape with a predetermined width. However, a conductive layer obtained by connecting a plurality of rectangular portions in a belt shape may be used. Then, a plurality of rectangular gap portions may be provided in the belt-shaped conductive layers. That is to say, a configuration may be employed in which lower conductive layers 12 and upper conductive layers 15 are formed with curable insulating layer 14 interposed therebetween such that rectangular portions and gap portions are alternately overlapped onto each other.

Furthermore, in the present embodiment, lower conductive layers 12 and upper conductive layers 15 are formed of a metal thin film of indium tin oxide, tin oxide, or the like, by a sputtering method or the like. However, they may be formed by dispersing thin lines of metal such as silver, or thin lines of carbon or the like, in translucent resin such as acrylic resin. Alternatively, they may be formed of translucent conductive resin such as polythiophene and polyaniline.

A touch panel in accordance with the present embodiment includes a small number of components and is less expensive. Furthermore, the touch panel has an advantageous effect that an operation can be carried out reliably, and is useful as an input device of various electronic apparatuses.

What is claimed is:

1. A touch panel comprising:
a translucent substrate;
a plurality of translucent lower conductive layers formed along a first direction of an upper surface of the substrate;
a translucent curable insulating layer covering entire surfaces of the lower conductive layers; and
a plurality of translucent upper conductive layers formed in a second direction perpendicular to the lower conductive layers and on an upper surface of the curable insulating layer.

2. The touch panel of claim 1,
wherein a part of each of the upper conductive layers is embedded in the curable insulating layer.

3. The touch panel of claim 1, further comprising:
a plurality of lower electrodes each having a first end connected to each of the lower conductive layers and a second end extending to an edge portion of the substrate; and
a plurality of upper electrodes each having a first end connected to each of the upper conductive layers, and a second end extending to an edge portion of the curable insulating layer.

4. The touch panel of claim 3,
wherein a part of each of the upper electrodes is embedded in the curable insulating layer.

5. The touch panel of claim 3,
wherein the curable insulating layer covers a part of the plurality of lower electrodes.

6. The touch panel of claim 1, further comprising:
a cover layer disposed on the curable insulating layer,
wherein the cover layer is brought into contact with upper parts of the upper conductive layers.

7. The touch panel of claim 1, further comprising:
a cover layer disposed on the curable insulating layer,
wherein a top view shows that an area of the curable insulating layer is larger than an area of the cover layer, and an area of the substrate is larger than the area of the curable insulating layer.

8. A method for manufacturing a touch panel, the method comprising:
forming a plurality of translucent lower conductive layers along a first direction of an upper surface of a translucent substrate;
forming a plurality of translucent upper conductive layers in a second direction perpendicular to the lower conductive layers and on a base material;
forming a translucent curable insulating layer so as to cover the upper conductive layers of the base material;
attaching a surface of the substrate having the lower conductive layers formed thereon to a surface of the base material having the curable insulating layer formed thereon;
hardening the curable insulating layer;
peeling off the base material from the curable insulating layer for forming the plurality of upper conductive layers a part of which is embedded in the curable insulating layer; and
forming a cover layer on an upper surface of the curable insulating layer.
